(19) United States
(12) Patent Application Publication
(10) Pub. No.: US 2025/0366295 A1
(43) Pub. Date: Nov. 27, 2025

(54) ELECTRONIC DEVICE

(71) Applicant: Samsung Display Co., LTD., Yongin-si (KR)

(72) Inventor: SANG MIN HONG, Yongin-si (KR)

(21) Appl. No.: 19/031,769

(22) Filed: Jan. 18, 2025

(30) Foreign Application Priority Data
May 22, 2024 (KR) 10-2024-0066390

(51) Int. Cl. H10H 29/855; H10H 29/80; H10H 29/85; H10K 59/126; H10K 59/38

(52) U.S. Cl. CPC H10H 29/8552; H10H 29/842; H10H 29/8517; H10K 59/126; H10K 59/38

(57) ABSTRACT

An electronic device includes a light-emitting element layer including a (1-1)-th typical light-emitting element and a (2-1)-th typical light-emitting element, a reflection preventing layer disposed on the light-emitting element layer, and including a light-shielding layer, in which a plurality of openings respectively corresponding to a (1-1)-th light-emitting area defined in the (1-1)-th typical light-emitting element, and a (2-1)-th light-emitting area defined in the (2-1)-th typical light-emitting element is defined, a light-shielding pattern disposed on the reflection preventing layer, and surrounding the (2-1)-th light-emitting area in a plan view, and a color filter pattern overlapping the light-shielding pattern, and surrounding the (2-1)-th light-emitting area in the plan view.

This application claims priority to Korean Patent Application No. 10-2024-0066390, filed on May 22, 2024, and all the benefits accruing therefrom under 35 U.S.C. § 119, the content of which in its entirety is herein incorporated by reference.

### BACKGROUND

### 1. Field

Embodiments of the disclosure described herein relate to an electronic device having an improved display quality.

### 2. Description of the Related Art

Electronic devices, such as televisions, mobile phones, tablet computers, navigation systems, game consoles, or the like, include display devices for displaying images. The display device may include an organic light-emitting display device. An organic light-emitting display device includes a light-emitting element, and the light-emitting element may generate light through recombination of electrons and holes. An organic light-emitting display devices has a relatively fast response speed and is driven with relatively low power consumption.

### SUMMARY

Embodiments of the disclosure provide an electronic device that shields light emitted at a relatively high angle in a screen having a different angle of view to improve a display quality.

In an embodiment of the disclosure, an electronic device includes a light-emitting element layer including a (1-1)-th typical light-emitting element and a (2-1)-th typical light-emitting element, a reflection preventing layer disposed on the light-emitting element layer, and including a light-shielding layer, in which a plurality of openings respectively corresponding to a (1-1)-th light-emitting area defined in the (1-1)-th typical light-emitting element, and a (2-1)-th light-emitting area defined in the (2-1)-th typical light-emitting element is defined, a light-shielding pattern disposed on the reflection preventing layer, and surrounding the (2-1)-th light-emitting area in a plan view, and a color filter pattern overlapping the light-shielding pattern, and surrounding the (2-1)-th light-emitting area in the plan view.

In an embodiment, the plurality of openings may include a first opening overlapping the (1-1)-th light-emitting area and a second opening overlapping the (2-1)-th light-emitting area, the first opening may be defined by a first sidewall of the light-shielding layer, and the second opening may be defined by a second sidewall of the light-shielding layer.

In an embodiment, the reflection preventing layer may further include a plurality of color filters disposed in the plurality of openings, respectively.

In an embodiment, an extent of the first opening may be greater than an extent of the second opening.

In an embodiment, in the plan view, the second sidewall of the light-shielding layer, which defines the second opening, may overlap the light-shielding pattern.

In an embodiment, in the plan view, the light-shielding pattern may have a ring shape.

In an embodiment, the color filter pattern may absorb light emitted from the (2-1)-th typical light-emitting element.

In an embodiment, the color filter pattern may correspond to a green color filter, and light emitted from the (2-1)-th typical light-emitting element is red light.

In an embodiment, the color filter pattern may correspond to a blue color filter, and light emitted from the (2-1)-th typical light-emitting element is red light.

In an embodiment, the electronic device may further include an over-coating layer disposed on the reflection preventing layer.

In an embodiment, the light-shielding pattern and the color filter pattern may be disposed between the reflection preventing layer and the over-coating layer, and the color filter pattern may be disposed between the light-shielding pattern and the over-coating layer.

In an embodiment, the light-shielding pattern may be disposed between the reflection preventing layer and the over-coating layer, and the color filter pattern may be spaced apart from the light-shielding pattern with the over-coating layer being interposed therebetween.

In an embodiment, the light-emitting element layer may further include a (1-2)-th typical light-emitting element, a (2-2)-th typical light-emitting element, a (1-3)-th typical light-emitting element, and a (2-3)-th typical light-emitting element, and the color filter pattern may not overlap a (2-2)-th light-emitting area defined in the (2-2)-th typical light-emitting element and a (2-3)-th light-emitting area defined in the (2-3)-th typical light-emitting element.

In an embodiment, the light-shielding pattern may be provided in plural, and in the plan view, a plurality of light-shielding patterns may surround the (2-1)-th light-emitting area, the (2-2)-th light-emitting area, and the (2-3)-th light-emitting area, respectively.

In an embodiment, the light-emitting element layer may be selectively driven in a first mode or a second mode, in the first mode, the (1-1)-th typical light-emitting element and the (2-1)-th typical light-emitting element may be driven, and in the second mode, the (1-1)-th typical light-emitting element may not be driven and the (2-1)-th typical light-emitting element may be driven.

In an embodiment of the disclosure, an electronic device includes a display layer including a (1-1)-th typical light-emitting element and a (2-1)-th typical light-emitting element, a reflection preventing layer disposed on the display layer, and including a light-shielding layer, in which a plurality of openings respectively corresponding to a (1-1)-th light-emitting area defined in the (1-1)-th typical light-emitting element, and a (2-1)-th light-emitting area defined in the (2-1)-th typical light-emitting element is defined, and an upper functional layer disposed on the reflection preventing layer, and the upper functional layer includes a light-shielding pattern disposed on the reflection preventing layer, and surrounding the (2-1)-th light-emitting area in a plan view, and a color filter pattern overlapping the light-shielding pattern, and surrounding the (2-1)-th light-emitting area in the plan view.

In an embodiment, the plurality of openings may include a first opening overlapping the (1-1)-th light-emitting area and a second opening overlapping the (2-1)-th light-emitting area, and an extent of the first opening may be greater than an extent of the second opening.

In an embodiment, the upper functional layer may further include an over-coating layer disposed on the reflection preventing layer.

In an embodiment, the light-shielding pattern and the color filter pattern may be disposed between the reflection preventing layer and the over-coating layer, and the color filter pattern may be disposed between the light-shielding pattern and the over-coating layer.

In an embodiment, the light-shielding pattern may be disposed between the reflection preventing layer and the over-coating layer, and the color filter pattern may be spaced apart from the light-shielding pattern with the over-coating layer being interposed therebetween.

### BRIEF DESCRIPTION OF THE DRAWINGS

The above and other embodiments, advantages and features of the disclosure will become apparent by describing in detail embodiments thereof with reference to the accompanying drawings.

FIG. 1 is a front view of an embodiment of an electronic device according to the disclosure.

FIG. 2 is a perspective view of an embodiment of an electronic device according to the disclosure.

FIG. 3 is a cross-sectional view of an embodiment of an electronic device according to the disclosure.

FIG. 4 is an enlarged plan view illustrating an embodiment of a partial area of a display layer according to the disclosure.

FIG. 5A is a cross-sectional view illustrating an embodiment of a portion of an electronic device according to the disclosure.

FIG. 5B is a cross-sectional view illustrating another portion of the electronic device according to the disclosure.

FIG. 6A is a plan view illustrating an embodiment of a portion of a light-shielding layer according to the disclosure.

FIG. 6B is a plan view illustrating an embodiment of a portion of a light-shielding pattern according to the disclosure.

FIG. 6C is a plan view illustrating an embodiment of a portion of a color filter pattern according to the disclosure.

FIG. 7 is a plan view illustrating an embodiment of portions of a light-shielding pattern and a color filter pattern according to the disclosure.

FIG. 8 is a cross-sectional view illustrating an embodiment of a portion of an electronic device according to the disclosure.

FIG. 9 is a cross-sectional view illustrating an embodiment of a portion of an electronic device according to the disclosure.

### DETAILED DESCRIPTION

In the specification, when it is mentioned that a component (or an area, a layer, a part, or the like) is “disposed on”, “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents. The term “and/or” includes one or more combinations that may be defined by the associated components.

Furthermore, in describing the various components, the terms, such as first and second may be used, but the disclosure is not limited by the terms. The terms are simply for distinguishing the components. For example, a first component may be named a second component, and similarly the second component also may be named the first component while not departing from the scope of the disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

In the specification, the expression of “directly disposed” may mean that none of a layer, a film, an area, and a plate is added between a part, such as the layer, the film, the area, and the plate, and another part. For example, the expression of “directly disposed” may mean that the two layers or two members are disposed while an additional member, such as an adhesive member, is not used therebetween.

Unless otherwise defined, all terms, including technical and scientific terms, used herein have the same meaning as commonly understood by those skilled in the art to which the disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

The terms “part” and “unit” refer to a software component or hardware component that performs a specific function. Hardware components may include, for example, a field-programmable gate array (“FPGA”) or an application-specific integrated circuit (“ASIC”). A software component may refer to an executable code and/or data used by the executable code in an addressable storage medium. Thus, for example, software components may be object-oriented software components, class components, and task components, and may include processes, functions, properties, procedures, subroutines, program code segments, drivers, firmware, microcodes, circuits, data, databases, data structures, tables, arrays. or may contain variables.

Hereinafter, embodiments of the disclosure will be described with reference to the drawings.

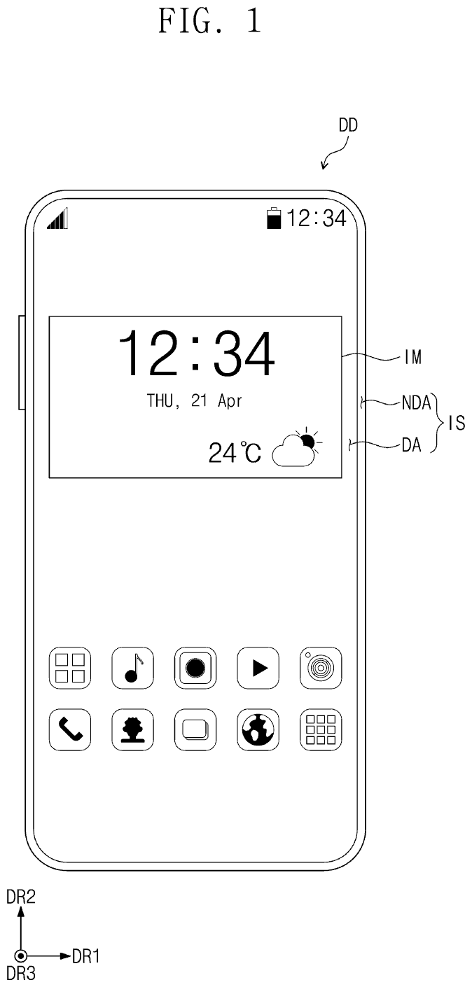

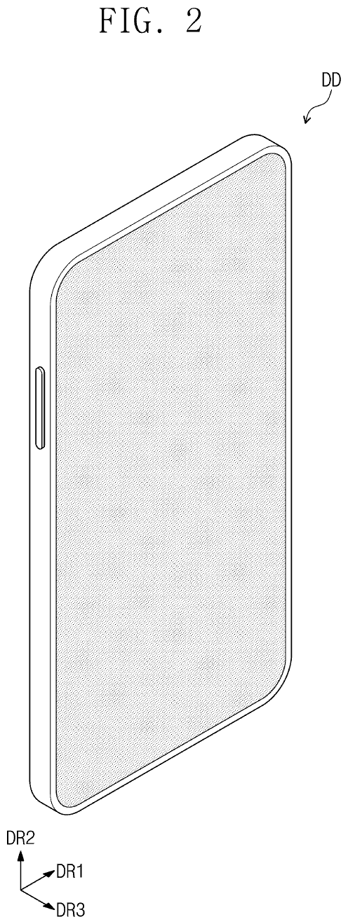

FIG. 1 is a front view of an embodiment of an electronic device DD according to the disclosure. FIG. 2 is a perspective view of an embodiment of an electronic device DD according to the disclosure.

Referring to FIGS. 1 and 2, the electronic device DD may be a device that is activated according to an electrical signal. The electronic device DD may be applied to electronic devices, such as mobile phones, tablets, smart watches, laptops, computers, and smart televisions.

The electronic device DD may display an image on a display surface IS parallel to a first direction DR1 and a second direction DR2. The display surface IS, on which the image is displayed, may correspond to a front surface of the electronic device DD. Images may include still images as well as dynamic images. A normal direction of the display surface IS, that is, a thickness direction of the electronic device DD is indicated by a third direction DR3. Front (or upper) and rear (or lower) surfaces of layers or units that will be described below are divided by the third direction DR3.

The display surface IS of an electronic device DD may be divided into a display area DA and a non-display area NDA. The display area DA may be an area in which an image is displayed. The user visually recognizes the image through the display area DA. In the embodiment, it is illustrated that the display area DA has a quadrangular shape, e.g., rectangular shape having rounded corners. However, this is illustrated as an illustrative embodiment, and the display area DA may have various shapes, and the disclosure is not limited to a particular embodiment.

The non-display area NDA is next (adjacent) to the display area DA. The non-display area NDA may have a predetermined color. The non-display area NDA may surround the display area DA. Accordingly, a shape of the display area DA may be substantially defined by the non-display area NDA. However, this is illustrated as an illustrative embodiment, and the non-display area NDA may be disposed next (adjacent) to only one side of the display area DA or may be omitted. The electronic device DD in an embodiment of the disclosure may include various embodiments, and the disclosure is not limited to a particular embodiment.

FIG. 1 may be a front view of the electronic device DD that is operated in a first mode or a second mode. FIG. 2 may be a side perspective view of the electronic device DD that is operated in the second mode. In an embodiment, the first mode may be a normal mode, in which a screen is displayed at a first angle of view, and the second mode may be a private mode, in which the screen is displayed at a second angle of view that is smaller than the first angle of view, for example. The first angle of view and the second angle of view may be defined as angles, at which an image quality may be viewed without distortion with respect to the normal direction of the display surface IS.

Referring to FIG. 1, in the first mode or the second mode, when the electronic device DD is viewed from the front side (or a direction that is parallel to the normal direction or the third direction DR3), images IM generated on the electronic device DD may be visually recognized to the user. In the second mode, when the electronic device DD is viewed from an angle that exceeds the second angle of view, the images IM may not be visually recognized.

The second angle of view of the second mode, and a luminance at the second angle of view may be variously set. When the electronic device DD is viewed at the angle that exceeds the second angle of view in the first mode, the user may visually recognize the images IM. In an embodiment, the second angle of view may be 45 degrees, and a luminance at 45 degrees may be 10 percent of a maximum luminance, for example. In the first mode, the luminance at 45 degrees may be 20 percent or more. However, the disclosure is not particularly limited thereto.

The electronic device DD may be selectively operated in any one of the first mode, in which the screen is displayed at the first angle of view, and the second mode, in which the screen is displayed at the second angle of view that is smaller than the first angle of view. Switching of the first mode and the second mode may be set by the user or the mode may be switched from the first mode to the second mode when a predetermined application is executed. In an embodiment, when an application, such as a banking or memo application, which has a risk of exposing personal information, is executed, the electronic device DD may be switched from the first mode to the second mode, for example.

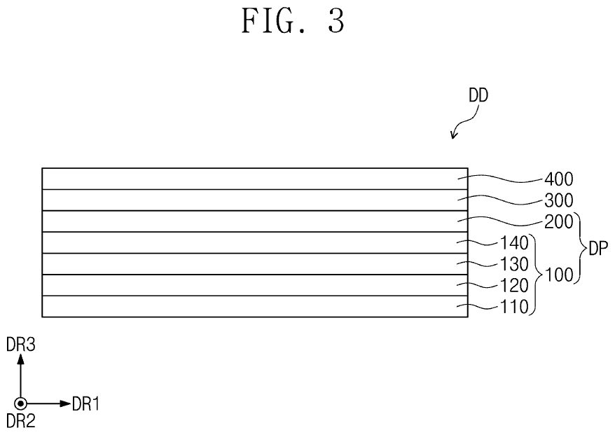

FIG. 3 is a cross-sectional view of an embodiment of the electronic device DD according to the disclosure.

Referring to FIG. 3, the electronic device DD may include a display panel DP, a reflection preventing layer 300, and an upper functional layer 400. However, this is only one of embodiments, and the electronic device DD may not include the upper functional layer 400 in another embodiment.

The display panel DP may include a display layer 100 and a sensor layer 200.

The display layer 100 may include a base layer 110, a circuit layer 120, a light-emitting element layer 130, and an encapsulation layer 140. The display layer 100 may be a component that actually generates images. The display layer 100 may be a light-emitting display layer, and for example, the display layer 100 may be an organic light-emitting display layer, an inorganic light-emitting display layer, an organic-inorganic light-emitting display layer, a quantum dot display layer, a micro light-emitting diode (“LED”) display layer, or a nano LED display.

The base layer 110 may be a member that provides a base surface, on which the circuit layer 120 is disposed. The base layer 110 may be a glass substrate, a metal substrate, a silicon substrate, or a polymer substrate. However, the disclosure is not limited thereto, and the base layer 110 may be an inorganic layer, an organic layer, or a composite material layer.

The circuit layer 120 may be disposed on the base layer 110. The circuit layer 120 may include an insulating layer, a semiconductor pattern, a conductive pattern, and a signal line. The insulating layer, the semiconductor layer, and the conductive layer may be formed on the base layer 110 through coating, deposition, or the like, and then an insulating layer, a semiconductor layer, and a conductive layer may be selectively patterned through a plurality of photolithography processes. Thereafter, the semiconductor pattern, the conductive pattern, and the signal line included in the circuit layer 120 may be formed.

The light-emitting element layer 130 may be disposed on the circuit layer 120. The light-emitting element layer 130 may include a light-emitting element. In an embodiment, the light-emitting element layer 130 may include an organic light-emitting material, an inorganic light-emitting material, an organic-inorganic light-emitting material, a quantum dot, a quantum rod, a micro LED, or a nano LED, for example.

The encapsulation layer 140 may be disposed on the light-emitting element layer 130. The encapsulation layer 140 may protect the light-emitting element layer 130 from foreign substances, such as moisture, oxygen, and dust particles.

The sensor layer 200 may detect external input applied from outside. The external input may be an input by the user. The input by the user may include various types of external inputs, such as a portion of the body of the user, light, heat, a pen, or a pressure. The sensor layer 200 may be also referred to as a sensor, an input sensing layer, or an input sensing panel. The sensor layer 200 may be formed through a continuous process with the display layer 100, and may be disposed directly on the display layer 100. However, the disclosure is not particularly limited thereto. In an embodiment, the sensor layer 200 may be coupled to the display layer 100 through an adhesion layer. The adhesive member may include a conventional adhesive.

The reflection preventing layer 300 may be disposed on the sensor layer 200. The reflection preventing layer 300 may decrease a reflectance of external light that is input from an outside of the electronic device DD. The reflection preventing layer 300 may be disposed directly on the sensor layer 200. However, the disclosure is not limited thereto, and an adhesive member may be disposed between the reflection preventing layer 300 and the sensor layer 200.

An upper functional layer 400 may be disposed on the reflection preventing layer 300. The upper functional layer 400 may serve to cover the reflection preventing layer 300. Furthermore, the upper functional layer 400 may serve as a planarizer. Because the light emitted from the light-emitting element layer 130 has to pass through the upper functional layer 400, the upper functional layer 400 may include an optically transparent material.

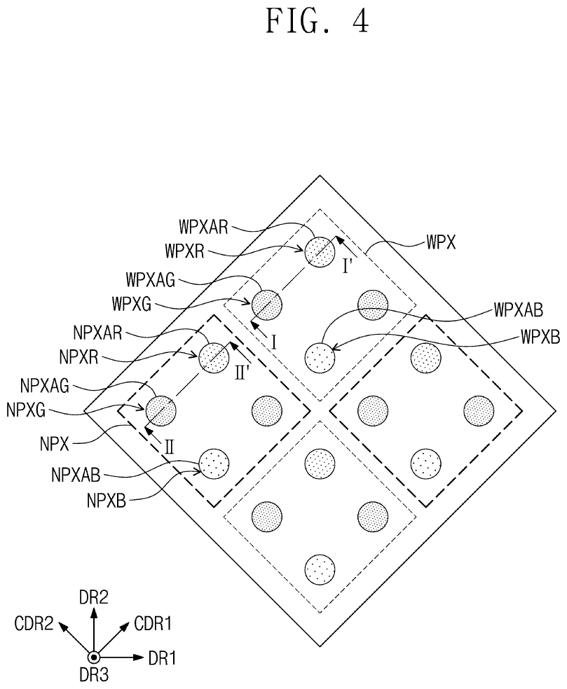

FIG. 4 is an enlarged plan view illustrating an embodiment of a partial area of the display layer 100 according to the disclosure.

Referring to FIG. 4, the display layer 100 may include a first pixel group WPX and a second pixel group NPX. The first pixel group WPX may include pixels having a relatively wide angle of view, and the second pixel group NPX may include pixels having a relatively narrow angle of view. The first pixel group WPX may include a (1-1)-th pixel WPXR, a (1-2)-th pixel WPXG, and a (1-3)-th pixel WPXB. The second pixel group NPX may include a (2-1)-th pixel NPXR, a (2-2)-th pixel NPXG, and a (2-3)-th pixel NPXB. Each of the first pixel group WPX and the second pixel group NPX may include one red pixel, one blue pixel, and two green pixels. However, this is only one of embodiments, and the number of the pixels may be different in another embodiment.

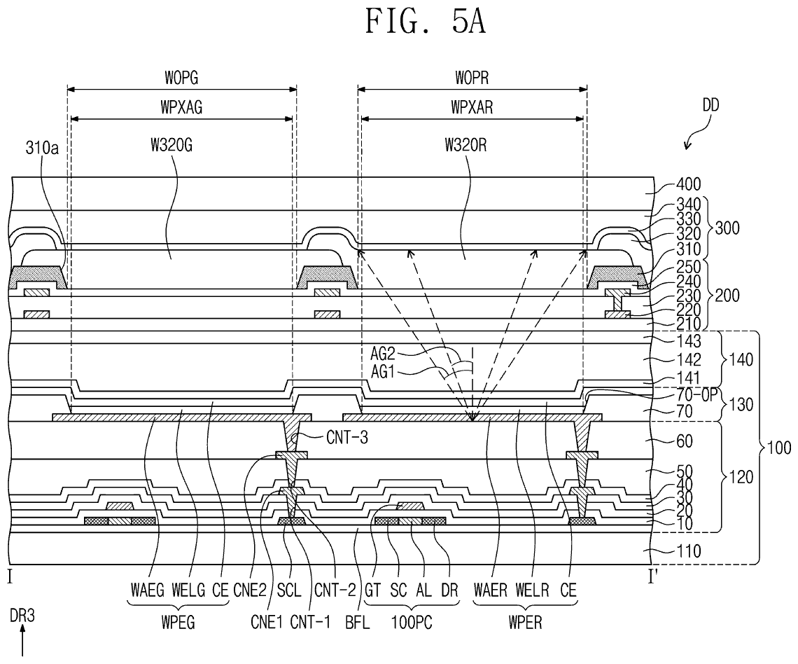

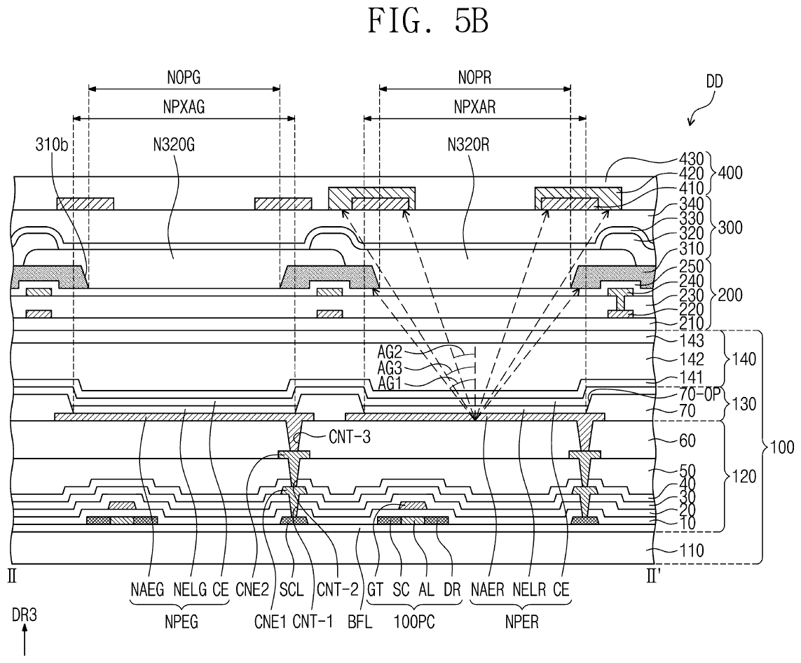

A (1-1)-th light-emitting area WPXAR may be defined in the (1-1)-th pixel WPXR, a (1-2)-th light-emitting area WPXAG may be defined in the (1-2)-th pixel WPXG, and the (1-3)-th pixel WPXB may be defined in a (1-3)-th light-emitting area WPXAB. The (1-1)-th light-emitting area WPXAR may be defined in a (1-1)-th typical light-emitting element WPER of the (1-1)-th pixel WPXR, which will be described in FIG. 5A, and the (1-2)-th light-emitting area WPXAG may be defined in a (1-2)-th typical light-emitting element WPEG of the (1-2)-th pixel WPXG, which will be described in FIG. 5A.

A (2-1)-th light-emitting area NPXAR may be defined in the (2-1)-th pixel NPXR, a (2-2)-th light-emitting area NPXAG may be defined in the (2-2)-th pixel NPXG, and the (2-3)-th light-emitting area NPXAB may be defined in the (2-3)-th pixel NPXB. The (2-1)-th light-emitting area NPXAR may be defined in a (2-1)-th typical light-emitting element NPER of the (2-1)-th pixel NPXR, which will be described in FIG. 5B, and the (2-2)-th light-emitting area NPXAG may be defined in a (2-2)-th typical light-emitting element NPEG of the (2-2)-th pixel NPXG, which will be described in FIG. 5B.

Hereinafter, the (1-1)-th to (1-3)-th light-emitting areas WPXAR, WPXAG, and WPXAB may be also referred to as the first light-emitting areas WPXAR, WPXAG, and WPXAB, and the (2-1)-th to (2-3)-th light-emitting areas NPXAR, NPXAG, and NPXAB may be also referred to as the second light-emitting areas NPXAR, NPXAG, and NPXAB.

The circular shapes illustrated in FIG. 4 may correspond to the shapes of the first light-emitting areas WPXAR, WPXAG, and WPXAB and the second light-emitting areas NPXAR, NPXAG, and NPXAB, respectively. However, the shapes of the first light-emitting areas WPXAR, WPXAG, and WPXAB and the second light-emitting areas NPXAR, NPXAG, and NPXAB are not limited thereto. In an embodiment, the first light-emitting areas WPXAR, WPXAG, and WPXAB and the second light-emitting areas NPXAR, NPXAG, and NPXAB may have various shapes, such as quadrangular (e.g., rectangular), polygonal, elliptical, triangular, or atypical shape in a plan view, for example.

In an embodiment of the disclosure, the (1-1)-th pixel WPXR and the (2-1)-th pixel NPXR, the (1-2)-th pixel WPXG and the (2-2)-th pixel NPXG, and the (1-3)-th pixel WPXB and the (2-3)-th pixels NPXB may have the same shapes, respectively. Furthermore, the (1-1)-th light-emitting area WPXAR and the (2-1)-th light-emitting area NPXAR, the (1-2)-th light-emitting area WPXAG and the (2-2)-th light-emitting area NPXAG, and the (1-3)-th light-emitting area WPXAB and the (2-3)-th light-emitting area NPXAB may have the same shapes, respectively.

In an embodiment of the disclosure, the first pixel group WPX and the second pixel group NPX may be alternately and repeatedly disposed in diagonal directions CDR1 and CDR2. The (1-1)-th pixels WPXR and (1-3)-th pixels WPXB of the first pixel group WPX may be alternately disposed one by one in the second direction DR2. Furthermore, the (2-1)-th pixels NPXR and the (2-3)-th pixels NPXB of the second pixel group NPX may be alternately disposed one by one in the second direction DR2. The (1-2)-th pixel WPXG of the first pixel group WPX may be disposed in diagonal directions CDR1 and CDR2 of the (1-1)-th pixel WPXR and the (1-3)-th pixel WPXB. The (2-2)-th pixel NPXG of the second pixel group NPX may be disposed in diagonal directions CDR1 and CDR2 of the (2-1)-th pixel NPXR and the (2-3)-th pixel NPXB.

The first diagonal direction CDR1 may be a direction between the first direction DR1 and the second direction DR2, and the second diagonal direction CDR2 may be a direction between an opposite direction to the first direction DR1, and the second direction DR2. However, an arrangement relationship of the (1-1)-th to (1-3)-th pixels WPXR, WPXG, and WPXB and the (2-1)-th to (2-3)-th pixels NPXR, NPXG, and NPXB illustrated in FIG. 4 is one of embodiments, and the arrangement relationship of the (1-1)-th to (1-3)-th pixels WPXR, WPXG, and WPXB and the (2-1)-th to (2-3)-th pixels NPXR, NPXG, and NPXB is not particularly limited thereto.

In an embodiment of the disclosure, each of the first pixel group WPX and the second pixel group NPX may be driven or not driven according to the first mode or the second mode. The first mode may be a normal mode, in which both the first pixel group WPX and the second pixel group NPX may be driven. The second mode may be a private mode, in which the first pixel group WPX is not driven and only the second pixel group NPX is driven.

FIG. 5A is a cross-sectional view illustrating an embodiment of a portion of the electronic device DD according to the disclosure. In an embodiment, FIG. 5A is a cross-sectional view including an embodiment of the display layer 100 according to the disclosure, taken along line I-I′ of the first pixel group WPX illustrated in FIG. 4, for example.

Referring to FIG. 5A, at least one inorganic layer is formed on an upper surface of the base layer 110. The inorganic layer may include at least one of aluminum oxide, titanium oxide, silicon oxide, silicon nitride, silicon oxynitride, zirconium oxide, and hafnium oxide. The inorganic layer may be formed in multi-layers. The multiple inorganic layers may constitute a barrier layer and/or a buffer layer. In the embodiment, it is illustrated that the display layer 100 includes a buffer layer BFL.

The buffer layer BFL may improve a coupling strength between the base layer 110 and the semiconductor pattern. The buffer layer BFL may include at least one of silicon oxide, silicon nitride, and silicon oxynitride. In an embodiment, the buffer layer BFL may include a structure, in which silicon oxide layers and silicon nitride layers are alternately laminated, for example.

A semiconductor pattern may be disposed on the buffer layer BFL. The semiconductor pattern may include poly-silicon. However, the disclosure is not limited thereto, and the semiconductor pattern may include amorphous silicon, low-temperature polycrystalline silicon, or an oxide semiconductor.

FIG. 5A only illustrates some semiconductor patterns, and additional semiconductor patterns may be disposed in other areas. The semiconductor patterns may be disposed in predetermined rules across the pixels. The semiconductor patterns may have different electrical properties depending on whether they are doped. The semiconductor patterns may include a first area having a relatively high conductivity and a second area having a relatively low conductivity. The first area may be doped with an N-type dopant or a P-type dopant. A P-type transistor may include a doped area that is doped with the P-type dopant, and an N-type transistor may include a doped area that is doped with the N-type dopant. The second area may be a non-doped area or an area doped at a lower concentration than that of the first area.

A conductivity of the first area is greater than that of the second area, and may substantially serve as an electrode or a signal line. The second area may substantially correspond to an active area (or channel) of the transistor. In other words, a part of the semiconductor pattern may be the active area of the transistor, another part may be a source or a drain of the transistor, and another part may be a connection electrode or a connection signal line.

Each of the pixels may include a pixel circuit and a light-emitting element. The pixel circuit may include a plurality of transistors and at least one capacitor.

A source area SC, an active area AL, and a drain area DR of a transistor 100PC may be formed from a semiconductor pattern. The source area SC and the drain area DR may extend in opposite directions from the active area AL in a cross-section. FIG. 5A illustrates a portion of a connection signal line SCL formed from a semiconductor pattern. Although not separately illustrated, the connection signal line SCL may be connected to the drain area DR of the transistor 100PC in a plan view.

A first insulating layer 10 may be disposed on a buffer layer BFL. The first insulating layer 10 may cover the semiconductor pattern while commonly overlapping the plurality of pixels. The first insulating layer 10 may be an inorganic layer and/or an organic layer, and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the embodiment, the first insulating layer 10 may be a single layer of silicon oxide. The insulating layer of the first insulating layer 10 as well as the circuit layer 120 that will be described later may be an inorganic layer and/or an organic layer, and may have a single-layer or multi-layer structure. The inorganic layer may include at least one of the above-mentioned materials, but the disclosure is not limited thereto.

A gate GT of a transistor 100PC is disposed on the first insulating layer 10. The gate GT may be a portion of a metal pattern. The gate GT overlaps the active area AL. In a process of doping a semiconductor pattern, the gate GT may function as a mask.

A second insulating layer 20 may be disposed on the first insulating layer 10, and may cover a gate GT. The second insulating layer 20 may commonly overlap the pixels. The second insulating layer 20 may be an inorganic layer and/or an organic layer, and may have a single-layer or multi-layer structure. The second insulating layer 20 may include at least one of silicon oxide, silicon nitride, and silicon oxynitride. In the embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer or multi-layer structure. In an embodiment, the third insulating layer 30 may have a multi-layer structure including a silicon oxide layer and a silicon nitride layer, for example.

A first connection electrode CNE1 may be disposed on the third insulating layer 30. The first connection electrode CNE1 may be connected to a connection signal line SCL through a contact hole CNT-1 that passes through the first, second, and third insulating layers 10, 20, and 30.

A fourth insulating layer 40 may be disposed on the third insulating layer 30. The fourth insulating layer 40 may be a single layer of silicon oxide. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 through a contact hole CNT-2 that passes through the fourth insulating layer 40 and the fifth insulating layer 50.

A sixth insulating layer 60 is disposed on the fifth insulating layer 50, and may cover the second connection electrode CNE2. The sixth insulating layer 60 may be an organic layer.

The light-emitting element layer 130 may be disposed on the circuit layer 120. The light-emitting element layer 130 may include first typical light-emitting elements WPER and WPEG, in which first light-emitting areas WPXAR and WPXAG are defined. In an embodiment, each of the first typical light-emitting elements WPER and WPEG may include an organic light-emitting material, an inorganic light-emitting material, an organic-inorganic light-emitting material, a quantum dot, a quantum rod, a micro LED, or a nano LED. Hereinafter, the first typical light-emitting elements WPER and WPEG will be described in an embodiment, in which each of the organic light-emitting elements is an organic light-emitting element, but the disclosure is not particularly limited thereto.

The first typical light-emitting elements WPER and WPEG may include a (1-1)-th typical light-emitting element WPER and a (1-2)-th typical light-emitting element WPEG. A cross-sectional structure of the (1-3)-th typical light-emitting element included in the (1-3)-th pixel WPXB (refer to FIG. 4) may be substantially the same as a cross-sectional structure of the (1-2)-th typical light-emitting element WPEG. Accordingly, in FIG. 5A, only the cross-sectional structures of the (1-1)-th typical light-emitting element WPER and the (1-2)-th typical light-emitting element WPEG are illustrated. Hereinafter, a description of the (1-3)-th typical light-emitting element will be omitted.

The typical light-emitting element WPER may include a (1-1)-th pixel electrode WAER, a (1-1)-th light-emitting layer WELR, and a common electrode CE. The (1-2)-th typical light-emitting element WPEG may include a (1-2)-th pixel electrode WAEG, a (1-2)-th light-emitting layer WELG, and a common electrode CE. The common electrode CE included in the (1-1)-th typical light-emitting element WPER and the (1-2)-th typical light-emitting element WPEG may be provided in an integral shape. The (1-1)-th pixel electrode WAER and the (1-2)-th pixel electrode WAEG may be also referred to as a first electrode or an anode. The common electrode CE may be also referred to as a second electrode or cathode.

FIG. 5A illustrates a cross-sectional view including two first typical light-emitting elements WPER and WPEG as an illustrative embodiment. Hereinafter, the (1-1)-th typical light-emitting element WPER will be representatively described. A description of (1-2)-th typical light-emitting elements WPEG may be substantially the same. Hereinafter, the (1-1)-th pixel electrode WAER is also referred to as a (1-1)-th electrode WAER, and the common electrode CE is also referred to as a second electrode CE.

The electrode WAER may be disposed on the sixth insulating layer 60. The (1-1)-th electrode WAER may be connected to the second connection electrode CNE2 through a contact hole CNT-3 that passes through the sixth insulating layer 60.

A pixel definition film 70 may be disposed on the sixth insulating layer 60, and may cover a portion of the (1-1)-th electrode WAER. A pixel definition opening 70-OP is defined in the pixel definition film 70. The pixel definition opening 70-OP of the pixel definition film 70 exposes at least a portion of the (1-1)-th electrode WAER.

The display area DA (refer to FIG. 1) may include first light-emitting areas WPXAR and WPXAG and a non-light-emitting area that is next (adjacent) to the first light-emitting areas WPXAR and WPXAG. The non-light-emitting area may surround the first light-emitting areas WPXAR and WPXAG. The first light-emitting areas WPXAR and WPXAG may be defined to correspond to the partial areas of the first electrodes WAER and WAEG, respectively. The (1-1)-th light-emitting area WPXAR may emit red light, and the (1-2)-th light-emitting area WPXAG may emit green light. In FIG. 5A, a cross-sectional structure of the (1-3)-th light-emitting area that may emit blue light is omitted, but the cross-sectional structure of the (1-3)-th light-emitting area is substantially the same as the cross-sectional structure of the (1-2)-th light-emitting area WPXAG.

The first light-emitting layers WELR and WELG may be disposed on the first electrodes WAER and WAEG, respectively. The (1-1)-th light-emitting layer WELR may be disposed in an area corresponding to the pixel definition opening 70-OP. That is, the first light-emitting layers WELR and WELG may be formed separately in the pixels. When the first light-emitting layers WELR and WELG are formed separately in the pixels, each of the first light-emitting layers WELR and WELG may emit light of at least one of red, green, and blue. However, the disclosure is not limited thereto, and the first light-emitting layers WELR and WELG may be connected to each other and may be commonly included in a plurality of light-emitting elements. In this case, the first light-emitting layers WELR and WELG may provide blue light or white light. In FIG. 5A, a (1-1)-th light-emitting layer WELR and a (1-2)-th light-emitting layer WELG are illustrated as an illustrative embodiment.

The second electrode CE may be disposed on the first light-emitting layers WELR and WELG. The second electrode CE may have an integrated shape, and may be commonly included in a plurality of pixels.

A hole control layer may be disposed between the first electrodes WAER and WAEG and the first light-emitting layers WELR and WELG. The hole control layer may include a hole transport layer, and may further include a hole injection layer. An electronic control layer may be disposed between the first light-emitting layers WELR and WELG and the second electrode CE. The electronic control layer may include an electron transport layer, and may further include an electron injection layer. The hole control layer and the electronic control layer may be commonly formed in a plurality of pixels by an open mask or inkjet process.

The encapsulation layer 140 may be disposed on the light-emitting element layer 130. The encapsulation layer 140 may include a first inorganic layer 141, an organic layer 142, and a second inorganic layer 143 that are sequentially laminated, but the layers that constitute the encapsulation layer 140 are not limited thereto. The first and second inorganic layers 141 and 143 may protect the light-emitting element layer 130 from moisture and oxygen, and the organic layer 142 may protect the light-emitting element layer 130 from foreign substances, such as dust particles. The first and second inorganic layers 141 and 143 may include a silicon nitride layer, a silicon oxynitride layer, a silicon oxide layer, a titanium oxide layer, or an aluminum oxide layer. The organic layer 142 may include an acrylic-based organic layer, but the disclosure is not particularly limited thereto.

The sensor layer 200 may be disposed on the display layer 100. The sensor layer 200 may be also referred to as a sensor, an input sensing layer, or an input sensing panel. The sensor layer 200 may include a sensor base layer 210, a first sensor conductive layer 220, an intermediate insulating layer 230, a second sensor conductive layer 240, and a sensor cover layer 250.

The sensor base layer 210 may be disposed directly on the display layer 100. The sensor base layer 210 may be an inorganic layer including at least one of silicon nitride, silicon oxynitride, and silicon oxide. In an alternative embodiment, the sensor base layer 210 may be an organic layer including epoxy resin, acrylic resin, or imide-based resin. The sensor base layer 210 may have a single-layer structure or a multi-layer structure that is laminated along the third direction DR3.

Each of the first sensor conductive layer 220 and the second sensor conductive layer 240 may have a single-layer structure or a multi-layer structure that is laminated along the third direction DR3.

The single-layer conductive layer may include a metal layer or a transparent conductive layer. The metal layer may include molybdenum (Mo), silver (Ag), titanium (Ti), copper (Cu), aluminum (Al), or alloys thereof. The transparent conductive layer may include a transparent conductive oxide, such as indium tin oxide, indium zinc oxide, zinc oxide, or indium zinc tin oxide. Furthermore, the transparent conductive layer may include conductive polymers such as poly(3,4-ethylenedioxythiophene) (“PEDOT”), metal nanowires, graphene, or the like.

The conductive layer of the multi-layer structure may include metal layers. The metal layers, for example, may have a three-layer structure of titanium/aluminum/titanium. The multi-layer conductive layer may include at least one metal layer and at least one transparent conductive layer.

An intermediate insulating layer 230 may be disposed between the first sensor conductive layer 220 and the second sensor conductive layer 240. The intermediate insulating layer 230 may include an inorganic membrane. The inorganic film may include at least one of aluminum oxide, titanium oxide, silicon oxide, silicon nitride, silicon oxynitride, zirconium oxide, and hafnium oxide.

In an alternative embodiment, the intermediate insulating layer 230 may include an organic layer. The organic film may include at least one of acrylic resin, methacrylic resin, polyisoprene, vinyl resin, epoxy resin, urethane resin, cellulose resin, siloxane resin, polyimide resin, polyamide resin, and perylene resin.

The sensor cover layer 250 may be disposed on the intermediate insulating layer 230, and may cover the second sensor conductive layer 240. The second sensor conductive layer 240 may include a conductive pattern. The sensor cover layer 250 may decrease or eliminate a probability of damage to the conductive pattern in a subsequent process while covering the conductive pattern. The sensor cover layer 250 may include an inorganic material. In an embodiment, the sensor cover layer 250 may include silicon nitride, for example, but the disclosure is not particularly limited thereto. In an embodiment of the disclosure, the sensor cover layer 250 may be omitted.

The reflection preventing layer 300 may be disposed on the sensor layer 200. The reflection preventing layer 300 may include a light-shielding layer 310, a plurality of first color filters 320, an inorganic layer 330, and a planarization layer 340.

The light-shielding layer 310 may be disposed to overlap the conductive pattern of the second sensor conductive layer 240. The sensor cover layer 250 may be disposed between the light-shielding layer 310 and the second sensor conductive layer 240. The light-shielding layer 310 may prevent reflection of external light by the second sensor conductive layer 240. A material that constitutes the light-shielding layer 310 is not particularly limited as long as it is a material that absorbs light. The light-shielding layer 310 is a layer with a black color, and in an embodiment, the light-shielding layer 310 may include a black coloring agent. A black ingredient may include a black dye and a black pigment. The black component may include metals, such as carbon black and chromium, or oxides thereof.

A plurality of openings WOPR and WOPG may be defined in the light-shielding layer 310. The openings WOPR and WOPG may correspond to the first light-emitting areas WPXAR and WPXAG defined in the first typical light-emitting elements WPER and WPEG, respectively, and may be also referred to as the first openings WOPR and WOPG. The first openings WOPR and WOPG may be defined by the first sidewall 310a of the light-shielding layer 310.

The first color filters 320 may include a (1-1)-th color filter W320R and a (1-2)-th color filter W320G. The (1-1)-th color filter W320R and the (1-2)-th color filter W320G may be disposed to correspond to the first openings WOPR and WOPG, respectively. The (1-1)-th color filter W320R and the (1-2)-th color filter W320G may transmit light that is emitted from the first typical light-emitting elements WPER and WPEG that overlap the (1-1)-th color filter W320R and the (1-2)-th color filter W320G. FIG. 5A illustrates two first openings WOPR and WOPG and two first color filters W320R and W320G as an illustrative embodiment.

In an embodiment of the disclosure, the inorganic layer 330 may be disposed over the first color filters 320. The inorganic layer 330 may be formed to cover the first color filters 320. Accordingly, the first color filters 320 and the light-shielding layer 310 may be protected from moisture and oxygen. The inorganic layer 330 may include a silicon nitride layer, a silicon oxynitride layer, a silicon oxide layer, a titanium oxide layer, or an aluminum oxide layer. Although the inorganic layer 330 is illustrated in FIG. 5A, this is an embodiment, and the inorganic layer 330 may be omitted.

The planarization layer 340 may cover the light-shielding layer 310 and the first color filters 320. The planarization layer 340 may include an organic material, and may provide a flat surface on an upper surface of the planarization layer 340. In an embodiment, the planarization layer 340 may be omitted.

In an embodiment of the disclosure, an upper functional layer 400 may be disposed on the reflection preventing layer 300. In an embodiment, the upper functional layer 400 may include an over-coating layer, for example. Accordingly, the reflection preventing layer 300 may be protected from an outside. However, this is only one of embodiments, and the upper functional layer 400 may be omitted in another embodiment.

In an embodiment of the disclosure, the first typical light-emitting elements WPER and WPEG may be driven or not be driven according to the first mode or the second mode. In the first mode that is the normal mode, the first typical light-emitting elements WPER and WPEG may be driven. Accordingly, the user may visually recognize the light emitted from the first typical light-emitting elements WPER and WPEG at both the first angle AG1 and the second angle AG2. In the second mode that is the private mode, the first typical light-emitting elements WPER and WPEG may not be driven.

FIG. 5B is a cross-sectional view illustrating an embodiment of another portion of the electronic device DD according to the disclosure. In an embodiment, FIG. 5B is a cross-sectional view including an embodiment of the display layer 100 in an embodiment of the disclosure taken along line II-II′ of the second pixel group NPX illustrated in FIG. 4, for example.

The cross-sectional structure of the (2-3)-th typical light-emitting element included in the (2-3)-th pixel NPXB (refer to FIG. 4) may be substantially the same as the cross-sectional structure of the (2-2)-th typical light-emitting element NPEG illustrated in FIG. 5B. Accordingly, in FIG. 5B, only the cross-sectional structures of the (2-1)-th typical light-emitting element NPER and the (2-2)-th typical light-emitting element NPEG are illustrated. Hereinafter, the description of (2-3)-th typical light-emitting elements will be omitted.

The cross-sectional view illustrated in FIG. 5A is a cross-sectional view including the first pixel group WPX having a relatively wide angle of view, and the cross-sectional view illustrated in FIG. 5B is a cross-sectional view including the second pixel group NPX having a relatively narrow angle of view. The base layer 110, the circuit layer 120, the encapsulation layer 140, and the sensor layer 200 of the display layer 100 illustrated in FIGS. 5A and 5B are substantially the same, and thus, a description thereof will be omitted.

Referring to FIG. 5B, the light-emitting element layer 130 may include second typical light-emitting elements NPER and NPEG in which, the second light-emitting areas NPXAR and NPXAG are defined. In an embodiment, each of the second typical light-emitting elements NPER and NPEG may include an organic light-emitting material, an inorganic light-emitting material, an organic-inorganic light-emitting material, a quantum dot, a quantum rod, a micro LED, or a nano LED, for example. Hereinafter, the second typical light-emitting elements NPER and NPEG will be described in an embodiment, in which each thereof is an organic light-emitting element, but the disclosure is not particularly limited thereto.

The second typical light-emitting elements NPER and NPEG may include a (2-1)-th typical light-emitting element NPER and a (2-2)-th typical light-emitting element NPEG. The (2-1)-th typical light-emitting element NPER may include a (2-1)-th pixel electrode NAER, a (2-1)-th light-emitting layer NELR, and a common electrode CE. The (2-2)-th typical light-emitting element NPEG may include a (2-2)-th pixel electrode NAEG, a (2-2)-th light-emitting layer NELG, and a common electrode CE. The common electrode CE included in the (2-1)-th typical light-emitting element NPER and the (2-2)-th typical light-emitting element NPEG may be provided in an integral shape. The (2-1)-th pixel electrode NAER and the (2-2)-th pixel electrode NAEG may be also referred to as a first electrode or an anode. The common electrode CE may be also referred to as a second electrode or cathode. The above-described second pixel electrodes NAER and NAEG and second light-emitting layers NELR and NELG may be substantially the same as the first pixel electrodes WAER and WAEG and first light-emitting layers WELR and WELG described in FIG. 5A, respectively.

FIG. 5B illustrates a cross-sectional view including two second typical light-emitting elements NPER and NPEG as an illustrative embodiment. A description of the second typical light-emitting elements NPER and NPEG illustrated in FIG. 5B may be substantially the same as the description of the first typical light-emitting elements WPER and WPEG illustrated in FIG. 5A.

The display area DA (refer to FIG. 1) may include second light-emitting areas NPXAR and NPXAG and a non-light-emitting area that is next (adjacent) to the second light-emitting areas NPXAR and NPXAG. The description of the second light-emitting areas NPXAR and NPXAG may be substantially the same as the description of the first light-emitting areas WPXAR and WPXAG of FIG. 5A.

In an embodiment of the disclosure, the reflection preventing layer 300 may include a light-shielding layer 310, in which a plurality of openings NOPR and NOPG is defined. The openings NOPR and NOPG may overlap the second light-emitting areas NPXAR and NPXAG defined in the second typical light-emitting elements NPER and NPEG, respectively, and may be also referred to as second openings NOPR and NOPG. The second openings NOPR and NOPG may be defined by the second sidewall 310b of the light-shielding layer 310. An extent of the first openings WOPR and WOPG corresponding to the first light-emitting areas WPXAR and WPXAG illustrated in FIG. 5A may be greater than an extent of the second openings NOPR and NOPG. Accordingly, an amount of light that is emitted from the second typical light-emitting elements NPER and NPEG and may be visibly recognized by the user will be smaller than an amount of light that is emitted from the first typical light-emitting elements WPER and WPEG and may be visibly recognized by the user. In an embodiment, in FIG. 5A, the user may visibly recognize the light at the first angle AG1, for example, but in FIG. 5B, the light is shielded by the light-shielding layer 310, and thus, the user may not visibly recognize the light at the first angle AG1.

The reflection preventing layer 300 may include second color filters N320R and N320G. The second color filters N320R and N320G may include a (2-1)-th color filter N320R and a (2-2)-th color filter N320G. The (2-1)-th color filter N320R and the (2-2)-th color filter N320G may be disposed to correspond to the second openings NOPR and NOPG, respectively. The (2-1)-th color filter N320R and the (2-2)-th color filter N320G may transmit light that is emitted from the second typical light-emitting elements NPER and NPEG that overlap the (2-1)-th color filter N320R and the (2-2)-th color filter N320G. FIG. 5B illustrates two second openings NOPR and NOPG and two second color filters N320R and N320G as an illustrative embodiment.

In an embodiment of the disclosure, the upper functional layer 400 may include a light-shielding pattern 410, a color filter pattern 420, and an over-coating layer 430.

The light-shielding pattern 410 may be disposed on the reflection preventing layer 300, and may be disposed to surround the second light-emitting areas NPXAR and NPXAG. The light-shielding pattern 410 may include or consist of substantially the same material as that of the light-shielding layer 310 of the reflection preventing layer 300. Accordingly, the light-shielding pattern 410 may include a black component that may prevent reflection of external light and absorbs light. In an embodiment of the disclosure, the light-shielding pattern 410 may be disposed to overlap the second sidewall 310b of the light-shielding layer 310 that defines the second openings NOPR and NOPG. Accordingly, compared to a structure in which only the light-shielding layer 310 is formed, when the light-shielding pattern 410 is formed together, a smaller angle of view may be displayed. When a smaller angle of view is formed, a strong private mode may be established, and privacy may be further protected. However, the disclosure is not limited thereto, and the light-shielding pattern 410 may not overlap the second sidewall 310b of the light-shielding layer 310.

In a plan view, the color filter pattern 420 may be formed to cover the light-shielding pattern 410 while overlapping the light-shielding pattern 410. A portion of the color filter pattern 420 may be disposed on the reflection preventing layer 300, and the remaining part may be disposed on the light-shielding pattern 410. The color filter pattern 420 may be disposed to surround the (2-1)-th light-emitting area NPXAR, and may not surround the (2-2)-th light-emitting area NPXAG. However, the disclosure is not limited thereto, and may be disposed to also surround the (2-2)-th light-emitting area NPXAG.

In an embodiment of the disclosure, the second typical light-emitting elements NPER and NPEG may be driven in both a first mode, which is a normal mode, and a second mode, which is a private mode. However, in the second mode, the first typical light-emitting elements WPER and WPEG (refer to FIG. 5A) may not be driven. Accordingly, the second mode may be displayed at the second angle of view that is smaller than the first angle of view of the first mode.

In an embodiment of the disclosure, the light-shielding pattern 410 may shield light emitted from the second typical light-emitting elements NPER and NPEG, and the color filter pattern 420 may absorb the light emitted from the corresponding (2-1)-th typical light-emitting elements NPER and NPEG. Then, the light emitted from the (2-1)-th typical light-emitting element NPER may be red light. Hereinafter, it will be described as an example that the light emitted from the (2-1)-th typical light-emitting element NPER is red light.

Comparing FIGS. 5A and 5B, the cross-sectional view illustrated in FIG. 5A may include a light-shielding layer 310, in which the first openings WOPR and WOPG are defined, but may not include a light-shielding pattern 410 and a color filter pattern 420. Accordingly, in the first mode, the light emitted from the (1-1)-th typical light-emitting element WPER at the first angle AG1 and the second angle AG2 may be visibly recognized by the user.

The cross-sectional view illustrated in FIG. 5B may include all of a light-shielding layer 310, in which second openings NOPR and NOPG are defined, a light-shielding pattern 410 that surrounds the second light-emitting areas NPXAR and NPXAG, and a color filter pattern 420 that surrounds the (2-1)-th light-emitting area NPXAR. As described above, an extent of the second openings NOPR and NOPG is smaller than an extent of the first openings WOPR and WOPG, the light emitted from the (2-1)-th typical light-emitting element NPER at the first angle AG1 may be shielded by the light-shielding layer 310, in which the second opening NOPR corresponding to the (2-1)-th typical light-emitting element NPER is defined, in the first mode and the second mode. Furthermore, the light that is emitted from the (2-1)-th typical light-emitting element NPER at the second angle AG2 may be shielded by the light-shielding pattern 410 that surrounds the (2-1)-th typical light-emitting element NPER. At this time, while being emitted from the (2-1)-th typical light-emitting element NPER, the light that travels at a third angle AG3 that is smaller than the first angle AG1 and is greater than the second angle AG2 may not be shielded by the light-shielding pattern 410. Accordingly, in the first mode and the second mode, the user may visually recognize a portion of the emitted light as the user moves from a relatively low angle to a relatively high angle with respect to a normal line. In an embodiment, when the light emitted from the (2-1)-th typical light-emitting element NPER is red light, the user may visually recognize the red light at the relatively high angle, for example.

However, while being emitted from the (2-1)-th typical light-emitting element NPER, the light that travels at the third angle AG3 that is smaller than the first angle AG1 and is greater than the second angle AG2 may be shielded by the color filter pattern 420 that overlaps the light-shielding pattern 410. When the light emitted from the (2-1)-th typical light-emitting element NPER is red light, the color filter pattern 420 may be a green color filter. As the color filter pattern 420 absorbs red light, a problem of images being visually recognized as red due to the red light emitted at a relatively high angle may be improved (or eliminated). Accordingly, a display quality may be improved even at relatively high angles. Then, when it may absorb light emitted from the (2-1)-th typical light-emitting element NPER, the color filter pattern 420 may be a blue color filter.

In an embodiment of the disclosure, an over-coating layer 430 may be disposed on the reflection preventing layer 300. Then, the light-shielding pattern 410 and the color filter pattern 420 may be disposed between the reflection preventing layer 300 and the over-coating layer 430. Furthermore, the color filter pattern 420 may be disposed between the light-shielding pattern 410 and the over-coating layer 430. Accordingly, the over-coating layer 430 may be formed to cover the reflection preventing layer 300, the light-shielding pattern 410, and the color filter pattern 420, and may protect the reflection preventing layer 300, the light-shielding pattern 410, and the color filter pattern 420. The over-coating layer 430 may include or consist of a transparent material because the light emitted from the first typical light-emitting elements WPER and WPEG (refer to FIG. 5A) and the second typical light-emitting elements NPER and NPEG has to be transmitted.

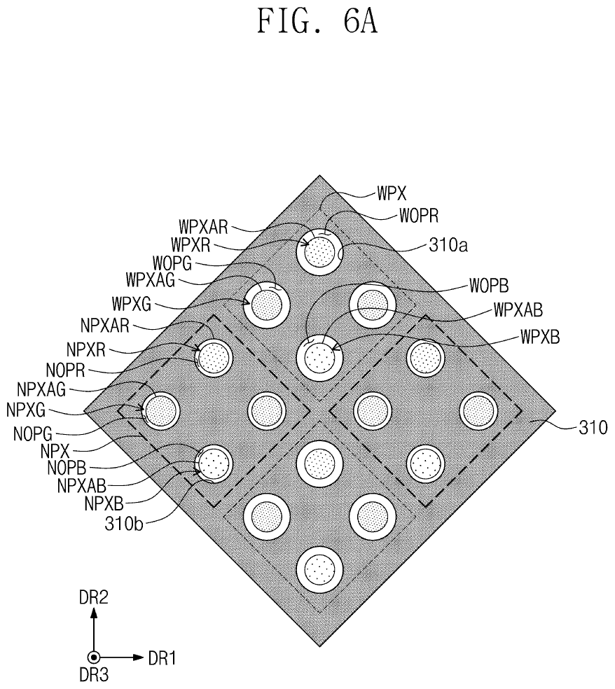

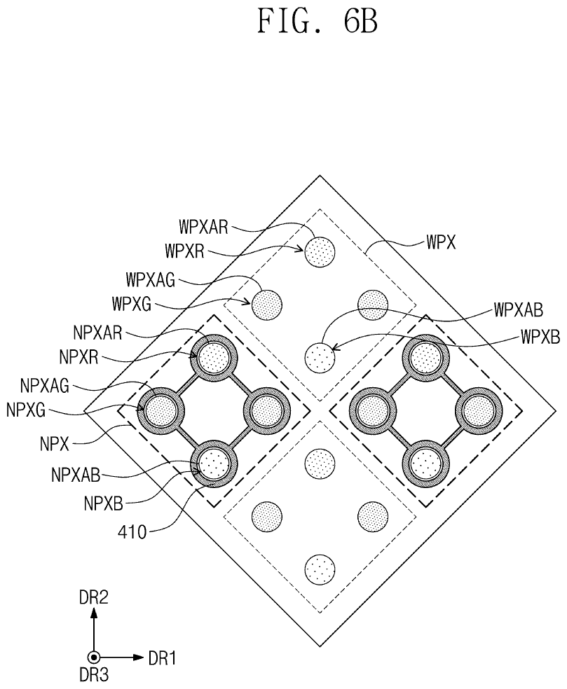

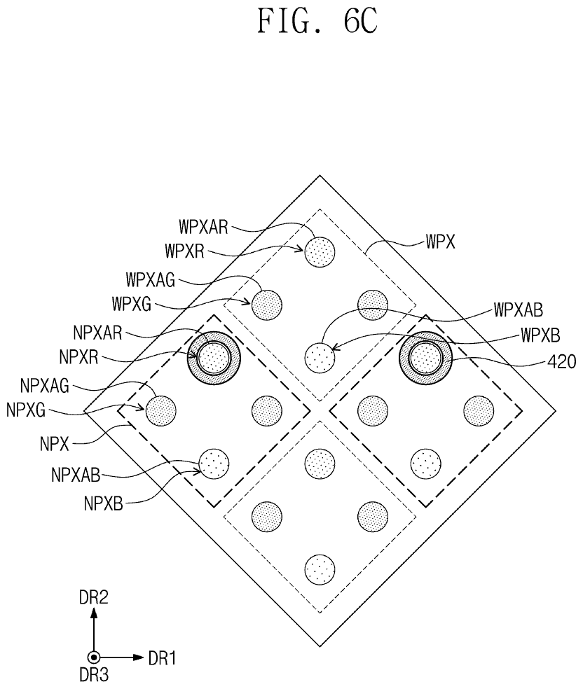

FIG. 6A is a plan view illustrating an embodiment of a portion of the light-shielding layer 310 according to the disclosure. FIG. 6A illustrates a plan view of the light-shielding layer 310 corresponding to the first pixel group WPX and the second pixel group NPX illustrated in FIG. 4.

Referring to FIG. 6A, a plurality of openings WOPR, WOPG, WOPB, NOPR, NOPG, and NOPB corresponding to the first light-emitting areas WPXAR, WPXAG, and WPXAB of the first pixel group WPX and the second light-emitting areas NPXAR, NPXAG, and NPXAB of the second pixel group NPX may be defined in the light-shielding layer 310. In an embodiment, the plurality of openings WOPR, WOPG, WOPB, NOPR, NOPG, and NOPB may include first openings WOPR, WOPG, and WOPB that overlap the first light-emitting areas WPXAR, WPXAG, and WPXAB, and second openings NOPR, NOPG, and NOPB that overlap the second light-emitting areas NPXAR, NPXAG, and NPXAB, for example.

The first openings WOPR, WOPG, and WOPB may be defined by the first sidewall 310a of the light-shielding layer 310, and the second openings NOPR, NOPG, and NOPB may be defined by the second sidewall 310b of the light-shielding layer 310. The light emitted from the first typical light-emitting elements WPER and WPEG (refer to FIG. 5A) of the first pixel group WPX may be visibly recognized by the user through the first openings WOPR and WOPG. The light emitted from the second typical light-emitting elements NPER and NPEG (refer to FIG. 5B) of the second pixel group NPX may be visibly recognized by the user through the second openings NOPR and NOPG. Accordingly, in the first mode, the user may visibly recognize the light through both the first openings WOPR, WOPG, and WOPB and the second openings NOPR, NOPG, and NOPB. In the second mode, the light may be visibly recognized only through the second openings NOPR, NOPG, and NOPB.

The extents of the first openings WOPR, WOPG, and WOPB and the second openings NOPR, NOPG, and NOPB defined in the light-shielding layer 310 may be different from each other, respectively. Accordingly, the angles of the light that may be visually recognized by the user may be different from each other. In an embodiment of the disclosure, the extents of the first openings WOPR, WOPG, and WOPB may be greater than the extents of the second openings NOPR, NOPG, and NOPB. Then, the user may have a relatively small angle of view in the second mode, which is different from that in the first mode.

FIG. 6B is a plan view illustrating an embodiment of a portion of the light-shielding pattern 410 according to the disclosure. FIG. 6B illustrates a plan view of the light-shielding pattern 410 corresponding to the first pixel group WPX and the second pixel group NPX illustrated in FIG. 4.

Referring to FIGS. 6A and 6B, the light-shielding pattern 410 may not be disposed on the first light-emitting area WPXAR, WPXAG, and WPXAB of the first pixel group WPX, and may only be disposed on the light-emitting area NPXAR, NPXAG, and NPXAB of the second pixel group NPX. The light-shielding pattern 410 may have a shape that surrounds the (2-1)-th light-emitting area NPXAR. Then, only the light-shielding layer 310 may be disposed on the first light-emitting area WPXAR, WPXAG, and WPXAB of the first pixel group WPX, and a light-shielding layer 310 and a light-shielding pattern 410 that surround the (2-1)-th light-emitting area NPXAR may be disposed on the (2-1)-th light-emitting area NPXAR of the second pixel group NPX. Accordingly, a high-angle light emitted from the (2-1)-th typical light-emitting element NPER (refer to FIG. 5B) may be shielded by the light-shielding pattern 410 even when it is not shielded by the light-shielding layer 310.

In an embodiment of the disclosure, the light-shielding pattern 410 may have a ring shape that surrounds the (2-1)-th light-emitting area NPXAR. However, this is only one of embodiments, and it may have a shape, such as a polygonal shape, other than a ring shape in another embodiment.

In an embodiment of the disclosure, a plurality of light-shielding patterns 410 may be provided. The plurality of light-shielding patterns 410 will be formed to surround not only the (2-1)-th light-emitting area NPXAR, but also the (2-2)-th light-emitting area NPXAG and the (2-3)-th light-emitting area NPXAB, respectively. As the light-shielding patterns 410 are disposed, both the light-shielding layer 310 and the light-shielding pattern 410 may be also disposed on the (2-2)-th light-emitting area NPXAG and the (2-3)-th light-emitting area NPXAB as in the (2-1)-th light-emitting area NPXAR. Accordingly, a high-angle light emitted from the (2-2)-th typical light-emitting element NPEG (refer to FIG. 5B) and the (2-3)-th typical light-emitting element NPEB (refer to FIG. 5B) may be shielded by the light-shielding pattern 410 even when it is not shielded by the light-shielding layer 310.

In an embodiment of the disclosure, the light-shielding patterns 410 may have shapes that are connected to each other. When the light-shielding patterns 410 are connected to each other, it is possible to prevent delamination that occurs due to external environments and processes. However, the disclosure is not limited thereto, and the light-shielding patterns 410 may have separate island shapes.

FIG. 6C is a plan view illustrating an embodiment of a portion of a color filter pattern 420 according to the disclosure. FIG. 6C illustrates a plan view of the color filter pattern 420 corresponding to the first pixel group WPX and the second pixel group NPX illustrated in FIG. 4.

Referring to FIGS. 6A, 6B, and 6C, the color filter pattern 420 may be disposed to surround the (2-1)-th light-emitting area NPXAR, the (2-2)-th light-emitting area NPXAG and the (2-3)-th light-emitting area NPXAB may not be surrounded. The color filter pattern 420 may absorb light emitted from the (2-1)-th typical light-emitting element NPER (refer to FIG. 5B). In an embodiment of the disclosure, the (2-1)-th typical light-emitting element NPER (refer to FIG. 5B) may emit red light, and a color filter pattern 420 disposed to surround the (2-1)-th light-emitting area NPXAR may be a green color filter that may absorb red light. However, the disclosure is not limited thereto, and the color filter pattern 420 may be a blue color filter that may absorb red light.

In an embodiment of the disclosure, only the light-shielding layer 310 that surrounds the first light-emitting areas WPXAR, WPXAG, and WPXAB may be disposed on the first pixel group WPX, and the light-shielding layer 310 and the light-shielding pattern 410 that surround the second light-emitting areas NPXAR, NPXAG, and NPXAB may be disposed on the second pixel group NPX. Furthermore, a color filter pattern 420 that surrounds the (2-1)-th light-emitting area NPXAR may be disposed on the second pixel group NPX. Because both the first pixel group WPX and the second pixel group NPX are driven in the first mode, and only the second pixel group NPX is driven in the second mode, the second angle of view in the second mode smaller than the first angle of view in the first mode. In an embodiment, the light that is emitted from the (2-2)-th typical light-emitting element NPEG (refer to FIG. 5B) of the (2-2)-th pixel NPXG driven in the second mode may be shielded by the light-shielding pattern 410 even though it is not shielded by the light-shielding layer 310, for example. Furthermore, the light that is emitted from the (2-1)-th typical light-emitting element NPER (refer to FIG. 5B) of the (2-1)-th pixel NPXR driven in the second mode may be shielded by the light-shielding pattern 410 even though it is not shielded by the light-shielding layer 310, and the high-angle light that is not shielded by the light-shielding pattern 410 may be shielded by the color filter pattern 420. Accordingly, the problem of images being visually recognized as red due to the high-angle emission light may be improved by the color filter pattern 420, and a display quality may be improved.

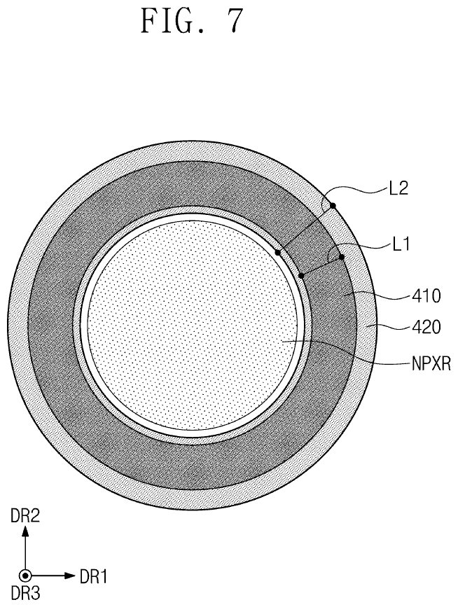

FIG. 7 is a plan view illustrating an embodiment of portions of the light-shielding pattern 410 and the color filter pattern 420 according to the disclosure.

Referring to FIG. 7, the light-shielding pattern 410 and the color filter pattern 420 may be disposed to surround the (2-1)-th light-emitting area NPXAR. Accordingly, the light emitted from the (2-1)-th typical light-emitting element NPER (refer to FIG. 5B) of the (2-1)-th pixel NPXR may be shielded by the light-shielding pattern 410 and the color filter pattern 420.

The light-shielding pattern 410 may have a first width L1, and the color filter pattern 420 may have a second width L2. The first width L1 and the second width L2 may correspond to the distances between the inner diameters and outer diameters of the light-shielding pattern 410 and the color filter pattern 420, respectively, when viewed in the third direction DR3.

In an embodiment of the disclosure, the first width L1 may be smaller than the second width L2. Accordingly, in a plan view, the color filter pattern 420 may overlap the entirety of the ring-shaped light-shielding pattern 410. When the first width L1 of the light-shielding pattern 410 is smaller than the second width L2 of the color filter pattern 420, the light emitted at a relatively high angle from the (2-1)-th typical light-emitting element NPER (refer to FIG. 5B) may be shielded by the color filter pattern 420 even though it is not shielded by the light-shielding pattern 410. In an embodiment, when the light emitted from the (2-1)-th typical light-emitting element NPER (refer to FIG. 5B) is red light, the red light emitted at a relatively high angle may be shielded by the color filter pattern 420 so that the display quality may be improved, for example. However, the disclosure is not limited thereto, and the widths of the light-shielding pattern 410 and the color filter pattern 420 may be the same, or the width of the light-shielding pattern 410 may be greater.

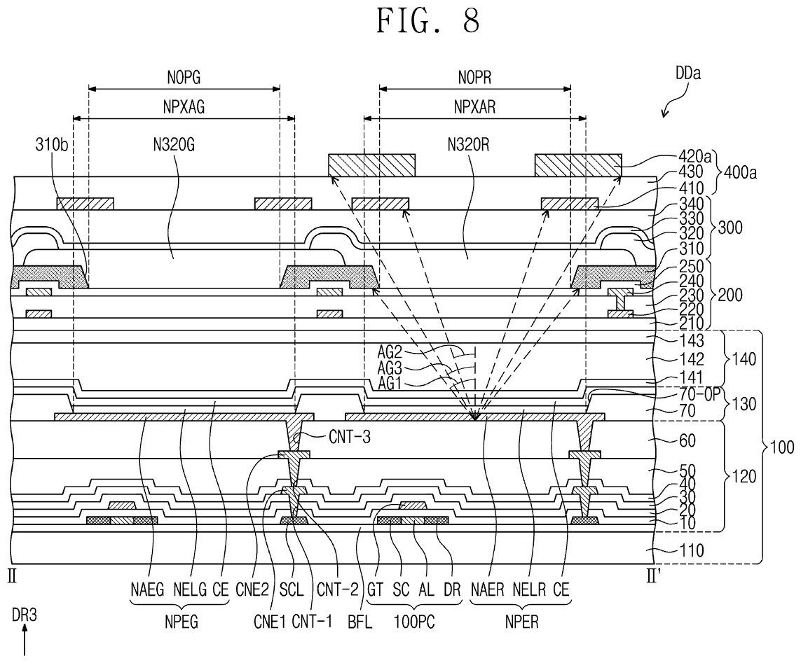

FIG. 8 is a cross-sectional view illustrating an embodiment of a portion of an electronic device DDa according to the disclosure. In an embodiment, FIG. 8 is a cross-sectional view taken along line II-II′ of the second pixel group NPX illustrated in FIG. 4, for example. In a description of FIG. 8, the same reference numerals as components described in FIG. 5B are used, and a description thereof will be omitted.

Referring to FIG. 8, the electronic device DDa may include a display layer 100, a sensor layer 200, a reflection preventing layer 300, and an upper functional layer 400a. The upper functional layer 400a may include a light-shielding pattern 410, a color filter pattern 420a, and an over-coating layer 430.

In an embodiment of the disclosure, the over-coating layer 430 may be disposed on the reflection preventing layer 300, and the light-shielding pattern 410 may be disposed between the reflection preventing layer 300 and the over-coating layer 430. Furthermore, the color filter pattern 420a may be disposed on the over-coating layer 430, and may be spaced apart from the light-shielding pattern 410 with the over-coating layer 430 being interposed therebetween. In a plan view, the color filter pattern 420a may surround the (2-1)-th light-emitting area NPXAR while overlapping the light-shielding pattern 410.

The color filter pattern 420a disposed on the over-coating layer 430 may absorb the light emitted from the (2-1)-th typical light-emitting element NPER. Even when the light-shielding pattern 410 does not shield the light emitted from the (2-1)-th typical light-emitting element NPER, the light emitted at a relatively high angle may be shielded by the color filter pattern 420a. In an embodiment, the light that travels at the first angle AG1, which is emitted from the (2-1)-th typical light-emitting element NPER, may be shielded by the light-shielding layer 310, and the light that travels at the second angle AG2 may be shielded by the light-shielding pattern 410, for example. Then, the light that travels at the third angle AG3, which is smaller than the first angle AG1 and greater than the second angle AG2, may be shielded by the color filter pattern 420a disposed on the over-coating layer 430.

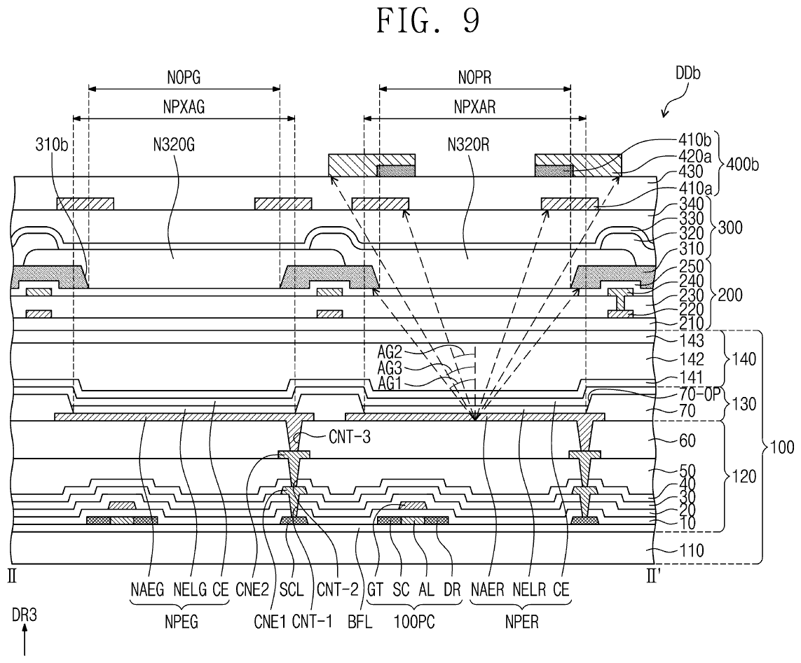

FIG. 9 is a cross-sectional view illustrating an embodiment of a portion of an electronic device DDb according to the disclosure. In an embodiment, FIG. 9 is a cross-sectional view taken along line II-II′ of the second pixel group NPX illustrated in FIG. 4, for example. In a description of FIG. 9, the same reference numerals as components described in FIG. 5B are used, and a description thereof will be omitted.

Referring to FIG. 9, the electronic device DDb may include a display layer 100, a sensor layer 200, a reflection preventing layer 300, and an upper functional layer 400b. The upper functional layer 400b may include a first light-shielding pattern 410a, a second light-shielding pattern 410b, a color filter pattern 420a, and an over-coating layer 430.

In an embodiment of the disclosure, the first light-shielding pattern 410a may be disposed on the reflection preventing layer 300. Furthermore, the second light-shielding pattern 410b and the color filter pattern 420a may be disposed on the over-coating layer 430. In a plan view, the color filter pattern 420a may overlap the first light-shielding pattern 410a and the second light-shielding pattern 410b. The color filter pattern 420a may be formed to cover the second light-shielding pattern 410b.

The first light-shielding pattern 410a may be formed to surround the second light-emitting areas NPXAR and NPXAG. The second light-shielding pattern 410b and the color filter pattern 420a may be formed to surround the (2-1)-th light-emitting area NPXAR, among the second light-emitting areas NPXAR and NPXAG. Accordingly, the light emitted from the (2-1)-th typical light-emitting element NPER may be shielded by the first light-shielding pattern 410a, the second light-shielding pattern 410b, and the color filter pattern 420a.

The high-angle emission light that is not shielded by the first light-shielding pattern 410a may be shielded by the second light-shielding pattern 410b and the color filter pattern 420a. In an embodiment, when the light emitted from the (2-1)-th typical light-emitting element NPER is red light, the high-angle red light that travels at the third angle AG3 that is smaller than the first angle AG1 and greater than the second angle AG2 may be shielded by the second light-shielding pattern 410b and the color filter pattern 420 whereby the display quality may be improved, for example.

According to the above, the electronic device may include the light-shielding pattern and the color filter pattern. The color filter pattern may absorb red light emitted at relatively high angles. Red light emitted at a relatively high angle may be shielded by the color filter pattern even through the light-shielding pattern cannot shield it. Accordingly, the display quality may be improved even at a relatively high angle by improving (or eliminating) the problem of images being visibly recognized as red due to the red light emitted at the relatively high angle.

Although the disclosure has been described with reference to the embodiments, it will be appreciated by an ordinary skilled in the art, to which the disclosure pertains, that the disclosure may be modified and changed within the scope of the appended claims without departing from the spirits and Field of the disclosure. Therefore, the technical scope of the disclosure should not be limited to the detailed description of the specification, but all the technical ideas in the claims and the equivalents to the claims fall within the scope of the disclosure.

What is claimed is:

1. An electronic device comprising:
a light-emitting element layer including:
a (1-1)-th typical light-emitting element; and
a (2-1)-th typical light-emitting element;
a reflection preventing layer disposed on the light-emitting element layer, and including:
a light-shielding layer, in which a plurality of openings respectively corresponding to a (1-1)-th light-emitting area defined in the (1-1)-th typical light-emitting element, and a (2-1)-th light-emitting area defined in the (2-1)-th typical light-emitting element is defined;
a light-shielding pattern disposed on the reflection preventing layer, and surrounding the (2-1)-th light-emitting area in a plan view; and
a color filter pattern overlapping the light-shielding pattern, and surrounding the (2-1)-th light-emitting area in the plan view.

2. The electronic device of claim 1, wherein the plurality of openings includes a first opening overlapping the (1-1)-th light-emitting area and a second opening overlapping the (2-1)-th light-emitting area,
wherein the first opening is defined by a first sidewall of the light-shielding layer, and
wherein the second opening is defined by a second sidewall of the light-shielding layer.

3. The electronic device of claim 2, wherein the reflection preventing layer further includes a plurality of color filters disposed in the plurality of openings, respectively.

4. The electronic device of claim 2, wherein an extent of the first opening is greater than an extent of the second opening.

5. The electronic device of claim 2, wherein in the plan view, the second sidewall of the light-shielding layer, which defines the second opening, overlaps the light-shielding pattern.

6. The electronic device of claim 1, wherein in the plan view, the light-shielding pattern has a ring shape.

7. The electronic device of claim 1, wherein the color filter pattern absorbs light emitted from the (2-1)-th typical light-emitting element.

8. The electronic device of claim 7, wherein the color filter pattern corresponds to a green color filter, and light emitted from the (2-1)-th typical light-emitting element is red light.

9. The electronic device of claim 7, wherein the color filter pattern corresponds to a blue color filter, and light emitted from the (2-1)-th typical light-emitting element is red light.

10. The electronic device of claim 1, further comprising:
an over-coating layer disposed on the reflection preventing layer.

11. The electronic device of claim 10, wherein the light-shielding pattern and the color filter pattern are disposed between the reflection preventing layer and the over-coating layer, and
wherein the color filter pattern is disposed between the light-shielding pattern and the over-coating layer.

12. The electronic device of claim 10, wherein the light-shielding pattern is disposed between the reflection preventing layer and the over-coating layer, and
wherein the color filter pattern is spaced apart from the light-shielding pattern with the over-coating layer being interposed therebetween.

13. The electronic device of claim 1, wherein the light-emitting element layer further includes a (1-2)-th typical light-emitting element, a (2-2)-th typical light-emitting element, a (1-3)-th typical light-emitting element, and a (2-3)-th typical light-emitting element, and
wherein the color filter pattern does not overlap a (2-2)-th light-emitting area defined in the (2-2)-th typical light-emitting element and a (2-3)-th light-emitting area defined in the (2-3)-th typical light-emitting element.

14. The electronic device of claim 13, wherein the light-shielding pattern is provided in plural, and
wherein in the plan view, a plurality of light-shielding patterns surrounds the (2-1)-th light-emitting area, the (2-2)-th light-emitting area, and the (2-3)-th light-emitting area, respectively.

15. The electronic device of claim 1, wherein the light-emitting element layer is selectively driven in a first mode or a second mode,
wherein in the first mode, the (1-1)-th typical light-emitting element and the (2-1)-th typical light-emitting element are driven, and
wherein in the second mode, the (1-1)-th typical light-emitting element is not driven and the (2-1)-th typical light-emitting element is driven.

16. An electronic device comprising:
a display layer including a (1-1)-th typical light-emitting element and a (2-1)-th typical light-emitting element;
a reflection preventing layer disposed on the display layer, and including a light-shielding layer, in which a plurality of openings respectively corresponding to a (1-1)-th light-emitting area defined in the (1-1)-th typical light-emitting element, and a (2-1)-th light-emitting area defined in the (2-1)-th typical light-emitting element is defined; and
an upper functional layer disposed on the reflection preventing layer, the upper functional layer including:
a light-shielding pattern disposed on the reflection preventing layer, and surrounding the (2-1)-th light-emitting area in a plan view; and
a color filter pattern overlapping the light-shielding pattern, and surrounding the (2-1)-th light-emitting area in the plan view.

17. The electronic device of claim 16, wherein the plurality of openings includes a first opening overlapping the (1-1)-th light-emitting area and a second opening overlapping the (2-1)-th light-emitting area, and
wherein an extent of the first opening is greater than an extent of the second opening.

18. The electronic device of claim 16, wherein the upper functional layer further includes an over-coating layer disposed on the reflection preventing layer.

19. The electronic device of claim 18, wherein the light-shielding pattern and the color filter pattern are disposed between the reflection preventing layer and the over-coating layer, and
wherein the color filter pattern is disposed between the light-shielding pattern and the over-coating layer.

20. The electronic device of claim 18, wherein the light-shielding pattern is disposed between the reflection preventing layer and the over-coating layer, and
wherein the color filter pattern is spaced apart from the light-shielding pattern with the over-coating layer being interposed therebetween.
